(19) United States
(12) Patent Application Publication
(10) Pub. No.: US 2012/0099254 A1
(43) Pub. Date: Apr. 26, 2012

(54) Ergonomic Portable Computer

(76) Inventors: David Rogers, Burbank, CA (US); Farida Mithaiwala, Aliso Viejo, CA (US)

(21) Appl. No.: 13/189,395

(22) Filed: Jul. 22, 2011

Related U.S. Application Data
(60) Provisional application No. 61/366,723, filed on Jul. 22, 2010.

(51) Int. Cl. H05K 7/00; F16B 17/00

(52) U.S. Cl. 361/679.01; 403/327

(57) ABSTRACT

A portable computer with ergonomic features comprises a height adjusting mechanism and a tilt adjusting mechanism for elevating the computer to a preferred viewing height and adjusting the viewing angle for an individual user.

### RELATED APPLICATION

This application claims the benefit under 35 U.S.C. §119 (e) of U.S. Provisional Patent Application No. 61/366,723 filed Jul. 22, 2010.

### FIELD OF THE INVENTION

The present invention relates generally to ergonomic portable computers and more specifically, it relates to laptop computers and notebook computers with an ergonomic design for positioning the monitor to a comfortable viewing position for the user so as to reduce the probability of physical injury brought on by inappropriate position of computer monitors for extended periods.

### BACKGROUND OF THE INVENTION

Over the last decade, use of computers has increased dramatically with the introduction of laptop computers and netbook computers. Laptop computers and netbook computers are designed to be compact and generally weigh significantly less than desk top computers to enable the portability of the computer. The design of laptop computers and notebook computers generally consists of a small display monitor pivotally attached to a base unit consisting of a built in keyboard and built in mouse. The base unit consists of the processing component of the computer, the hard-drive, CD-ROM/DVD drive and other components. Laptop computers and notebook computers are increasingly becoming the computer of choice for many computer users. While these laptop computers and notebook computers offer greater flexibility over desk top computers, they do come with certain inherent problems. The laptop computers and notebook computers keyboards are relatively small and make it more difficult for the user to use over an extended period of time due to the often poor posture caused by the positioning of the hands/wrists on the small keyboard and the relatively lower position display monitor. The height of the laptop computers and notebook computers display monitor is typically much lower than a desired position such that an individual does not experience neck strain when looking at the display monitor over an extended period of time. The height of the typical laptop computer display monitor screen is generally no more than 10 to 14 inches tall and is affixed to the keyboard whereby the user often has to tilt his or her head down in order to look at the screen. With continued use of a laptop computer or notebook computer, it is not uncommon for the user to experience strain in the neck and upper back areas and such strain often leads to injuries. The incidence of physical harm to users resulting from the continued use of laptop computers and notebook computers is believed to be increasingly common.

Recently, laptop support stands have been provided that attempt to solve some of the inherent problems with ergonomic deficiencies involving laptop computers and netbook computers. Unfortunately, these attempted solutions are typically bulky, heavy, and defeat the portability feature of the laptop.

In view of the foregoing, the portable computer according to the present invention provides significant improvements from the conventional designs that are currently available, and provides ergonomic portable computers that overcome the limitations of conventional portable computers.

### SUMMARY OF THE INVENTION

The invention provides a portable computer with a new capability with respect to positioning the computer display screen to fit the needs of an individual user. The novel features of the invention consists of integral mechanisms for elevating and tilting or pivoting the display monitor screen to desired height and viewing angle such that the screen can be adjusted in a vertical direction and can be adjusted in tilt whereby the user can achieve enhanced working posture and enhanced ergonomic function. In a first aspect, the invention provides for a vertically adjustable display screen. In a second aspect, the invention provides for the display screen to pivot along its top edge whereby the user can adjust the tilt of the display screen to a desired viewing angle. In yet another aspect, the invention provides for a built-in reference material stand for displaying documents when the display screen is an elevated position.

The specific features of the invention will become apparent in the course of the following detailed description when read in conjunction with the attached drawings.

It is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of the description and should not be regarded as limiting.

The portable computer includes a main unit and a display unit, commonly referred to as a monitor or screen of a computer. The main unit is connected to the display unit via a rotating hinge mechanism. The display unit consists of three panels or layers that together collectively form the upper aspect of the portable computer (and the upper cover of the portable computer when the computer is in a closed position). The three panels of the display unit are the display screen panel, the interior panel and the base panel. The display screen panel comprises an LCD or LED screen. The wiring/cable and electrical connectivity from the main unit runs in a conduit within the base panel of the display unit to the interior panel of the display unit to the display screen panel of the display unit. The interior panel and display panel screen of the display unit can be ergonomically adjusted in their combined height by moving up or down via a controlled interlocking mechanism as is described in further detail below (functioning between the base panel of the display unit and the interior panel of the display unit). The movement may be performed in an incremental fashion whereby the display screen height can be adjusted to several different positions suitable for any given user. The controlled interlocking mechanism of the Invention locks and unlocks mechanically to allow the height of the interior panel and display screen panel of the display unit to adjust up or down. When the interior panel and display screen panel of the display unit are in an elevated position, the base panel becomes partially exposed and during use provides a back support to function as a reference material stand for displaying documents such as reference materials.

### BRIEF DESCRIPTION OF THE DRAWINGS

FIG. 1 is a perspective view of the portable computer with the interior panel and display screen panel of the display unit set at its lowest height with respect to the main unit.

FIGS. 2a and 2b provide a front view of the portable computer with two different levels of elevation of the interior panel and the display screen panel of the display unit according to an embodiment of the invention.

FIG. 3a provides a perspective view of the portable computer with an elevated and forwardly tilted display screen panel and interior panel according to an embodiment of the invention. FIG. 3b provides a side view of this embodiment, and FIG. 3c shows the portable computer in a fully closed position.

FIG. 4 provides an illustration of a use of the invention such that the display screen of a portable computer is raised to be directly in the line of vision of the user.

FIG. 5a provides a detailed view of the interlocking mechanism of the invention illustrating a locked position.

FIG. 5b illustrates an unlocked position of the interlocking mechanism.

FIGS. 5c and 5d illustrate the press button actuated movement of the display screen panel and the interior panel upwards and out of the base panel, and fixed in an elevated position.

FIG. 6a provides a detailed view of the internal assembly of the interlocking mechanism comprising a pin and rack element, including compression spring components and a mobile housing assembly, and further illustrating the extension of the pin out of the mobile housing component and into a slot on the vertical rack.

FIG. 6b illustrates the retraction of the pin within the mobile housing component.

FIGS. 7a and 7b provide an expanded view of the movement of the pin within and out of he mobile housing assembly.

FIGS. 8a and 8b provide a top down view of the pin when it is housed within the mobile housing assembly and when it is protruded out of the mobile housing assembly and contained within a slot on the vertical rack, respectively.

FIGS. 9a and 9b illustrate an embodiment of the invention comprising a spring loaded pivotable locking mechanism.

### DETAILED DESCRIPTION OF THE INVENTION

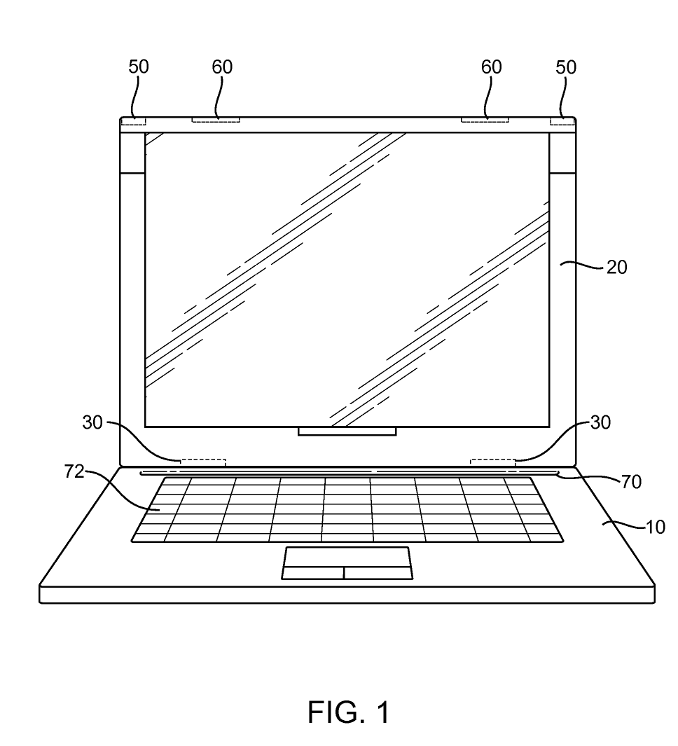

Referring to FIG. 1, an embodiment of a portable computer in accordance with the invention is shown. The laptop has a main unit 10 and a display unit 20 that are connected together by hinges 30. The hinges 30 enable the display unit and main unit to rotate relative to each other in a clam-shell like manner about the X-axis. Along the top edge of the display unit 20, is a pair of buttons 50. The buttons function as a means to trigger the controlled mechanism to enable the movement of the display panel and the interior panel upward or downward. The main unit comprises a keyboard 72 and a groove or channel 70 located on the top surface of the main unit 10 along the X-axis and closest to the posterior edge of the main unit. This groove or channel may be used to hold reference material while the computer is in use with the display panel in an elevated position.

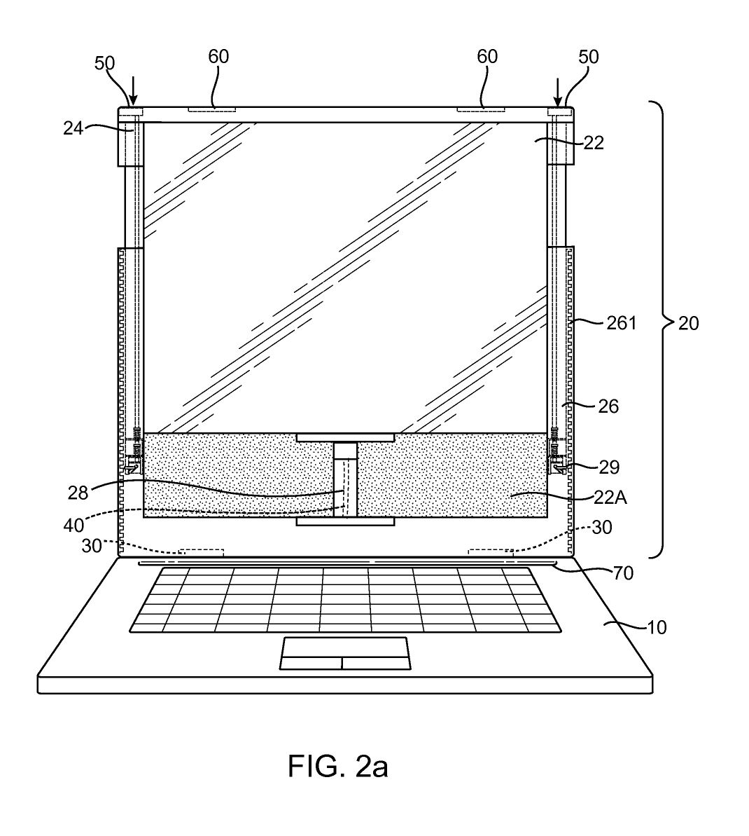

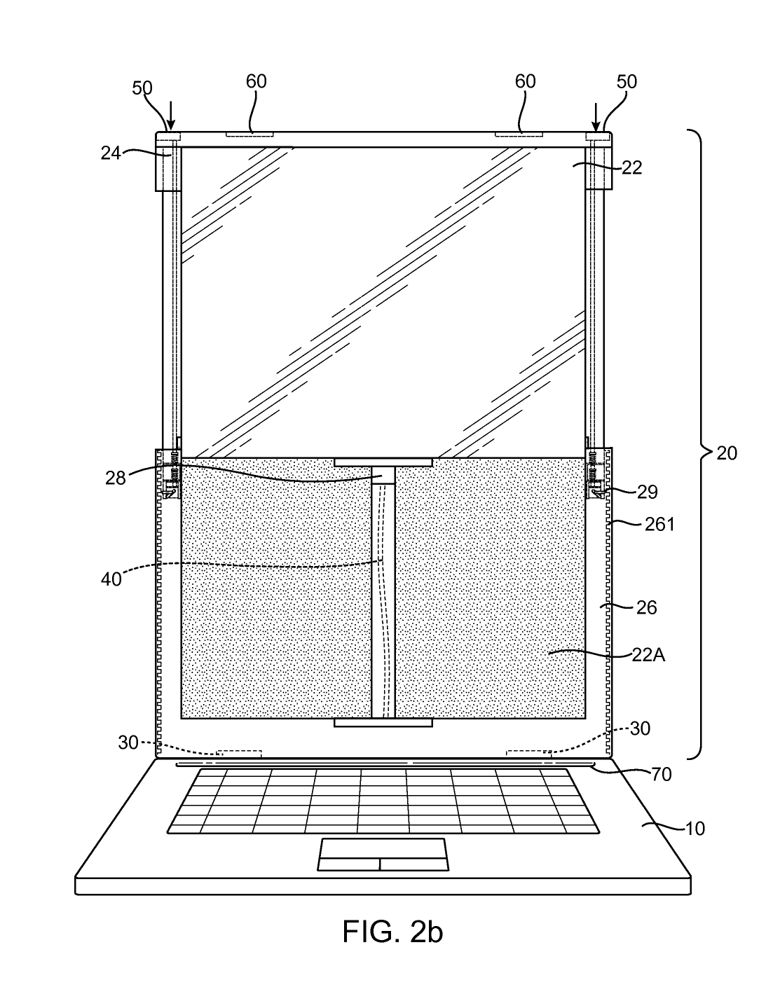

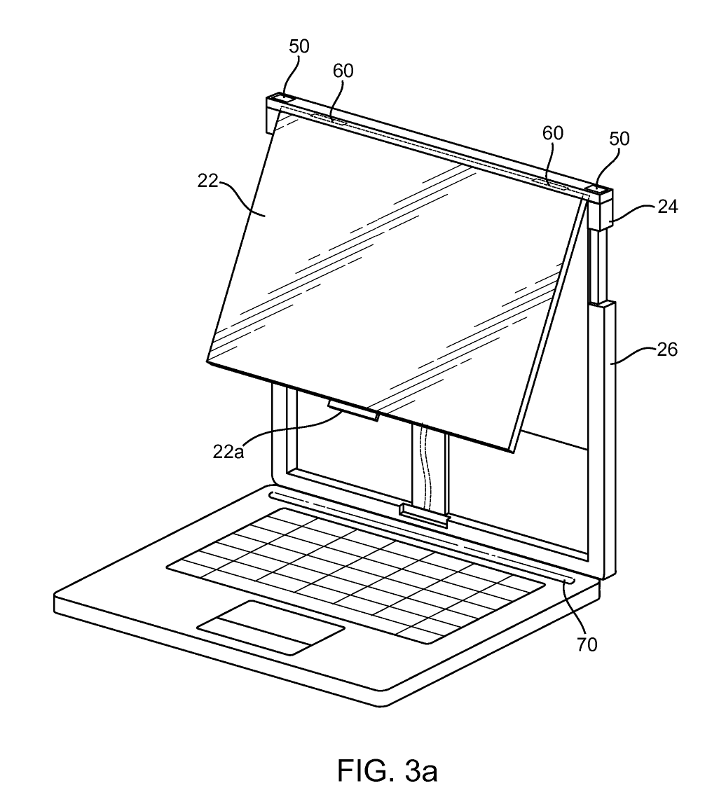

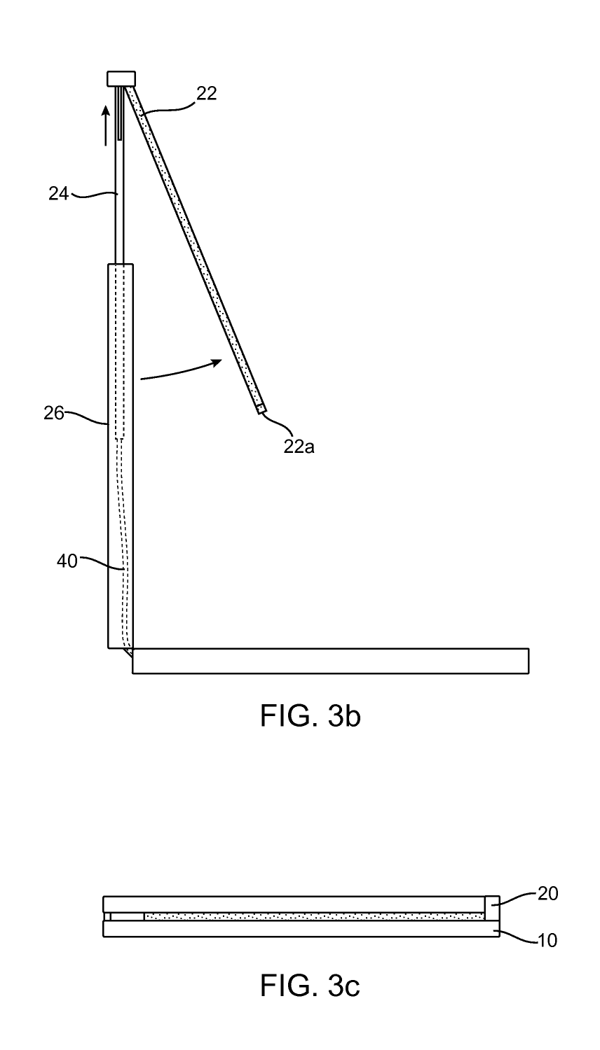

FIG. 2a shows a preferred embodiment of the invention wherein the display screen panel and interior panel of the display unit are elevated in accordance with the height adjusting mechanism of the invention. The base panel 26 of the display unit 20 consists of a plurality of slots to form a vertical rack 261 along the left and right sides parallel to the Y-axis. The left and right vertical racks 261 in the base panel 26 are fixed and receive the left and right locking pins 29 of the movable housing assembly. The display panel is elevated by depressing in the left and right press buttons 50 which are connected to a push rod 35 that is spring loaded by virtue of compression springs which triggers the movement of the locking pin 29 out and away from the slot 261 and into retracts it further into the recess or cavity 32 of the movable housing assembly. By disengaging the locking pin from the vertical rack, the user can freely raise the interior panel and display panels along the Y-axis to a desired elevation. Upon release of the left and right buttons 50, the locking pin 29 re-engages with the vertical rack 261 and secures the interior panel and display panel to prevent any further vertical, upward or downward movement. The display panel may be elevated to multiple heights to provide a user flexibility in setting the height to the user's preferred viewing elevation of the display panel. In a preferred aspect of the Invention, the display panel and interior panel are simultaneously elevated to a height at least 50% higher than when the display panel is in its original un-elevated or resting position. In another aspect, the display panel (along with the interior panel) is elevated to a height of at least about eight inches from the main unit. The preferred embodiment of the Invention is to elevate the display panel to a distance such that the center of the display panel when measured along the Y-axis is in the same plane as an individual's line of vision. FIG. 3d shows a schematic of such an embodiment of the Invention. Also shown in FIGS. 2a and 2b is a conduit 28 located in the center of the base panel, along the Y-axis. A flexible cable 40 is contained within the conduit 28 of the base panel 26 and provides an electrical connection between the main unit 10 and the display screen panel 22 (via the interior panel 24).

FIG. 2b shows a computer of the invention wherein the display screen panel and interior panel of the display unit 20 are in a fully elevated position and locked in place. A plurality of slots of the vertical rack 261 arranged in a vertical manner along an inner surface of the base panel 26 are engaged with the locking pin 29. One of skill will recognize that the movement and locking mechanisms are not limited to those described herein and that alternate means of controlling the movement of the display panel and locking it securely in place could be used.

FIGS. 3a and 3b show perspective and side views of an embodiment of the invention wherein the display screen panel 22 is pivoted along its top edge. It should be noted that the pivot angle may be adjusted to various degrees whereby the tilt of the display screen panel may be adjusted for any desired viewing position. It should be noted that the tilt position or angle may be set to any degree of angle as desired by the user. Referring to FIG. 3a, the display screen panel 22 is rotationally coupled with the interior panel 24 with hinges 60. The hinges 60 enable the movement of the display screen panel 22 away and toward the interior panel 24 in a clam shell like manner. In a closed position, the display screen panel and interior panel are parallel and flush against each other. The user can rotate the display screen panel 22 towards the front by simply raising the bottom edge 22A of the display screen panel 22 towards the front. The hinges 60 allow for the display screen panel 22 to be held firmly at the desired viewing angle without collapsing against the interior panel 24.

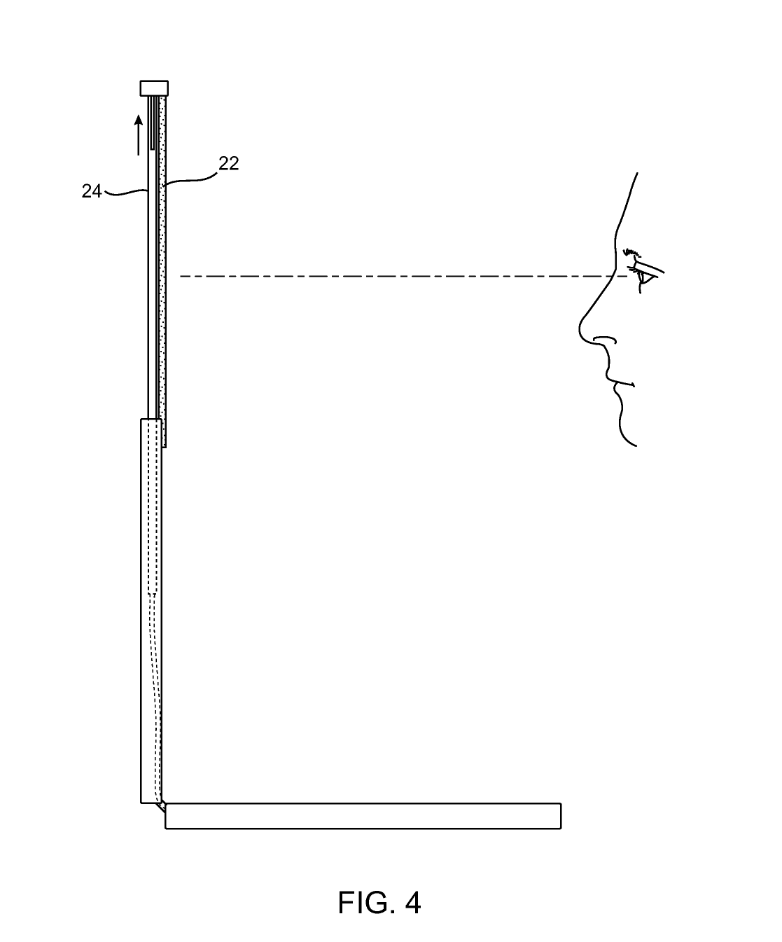

During use, a user of the portable computer will press the buttons 50 located on the left and right corners of the display panel to actuate a spring loaded locking mechanism to unlock the interior panel and the display panel from the base panel so as to allow the user to raise the monitor to a desired height. FIG. 4 illustrates a use wherein the monitor is raised to a height such that the height of the center of the display panel coincides with the user's line of vision. In other words, the center of the LCD screen is directly across the user's eyes resulting in the prevention of muscular strain in the user's back or neck muscles.

Interlocking Mechanisms

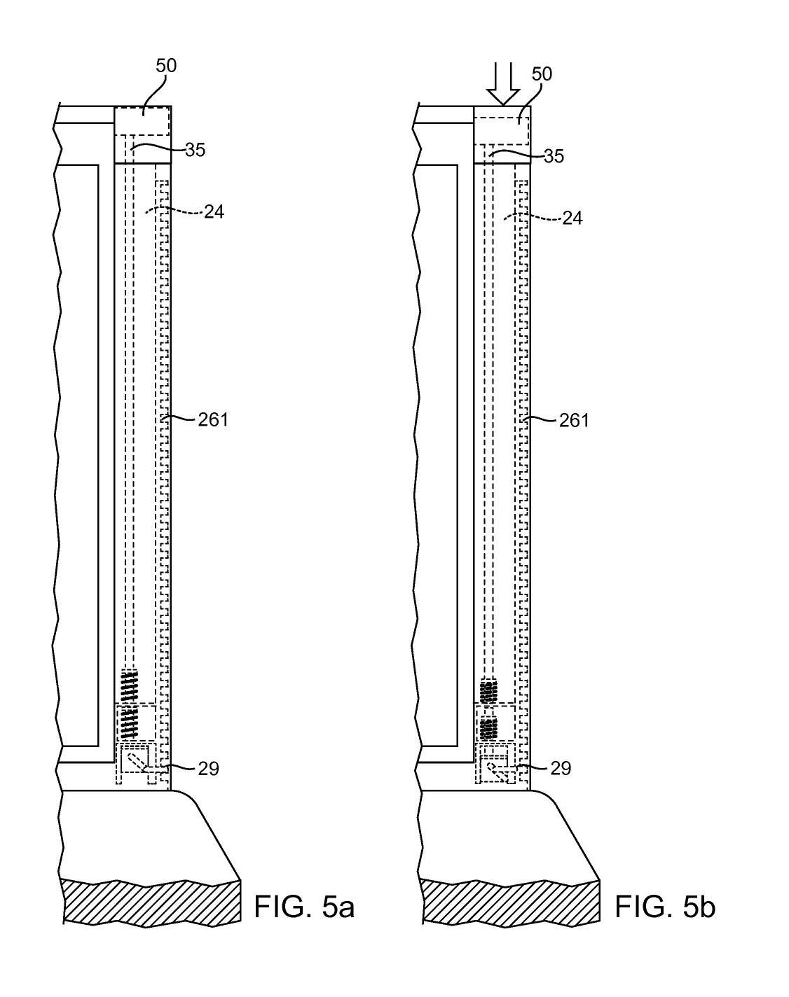

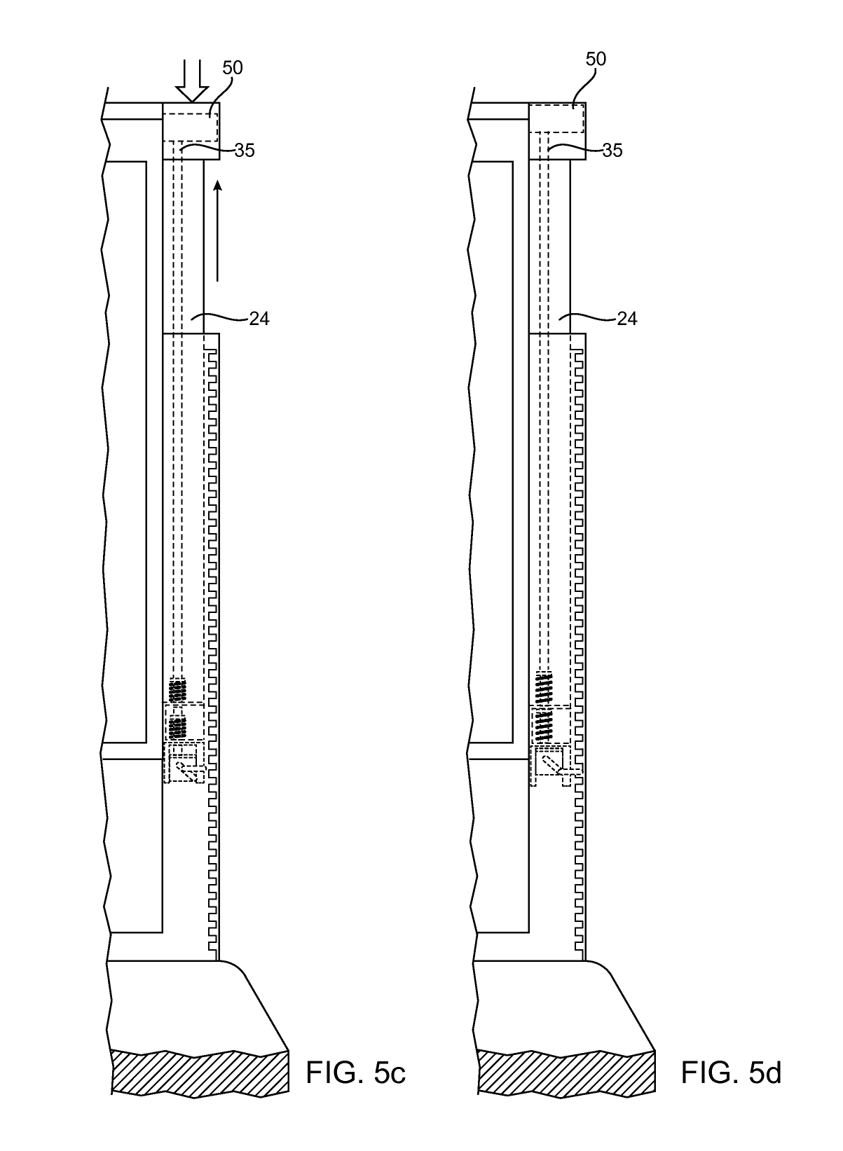

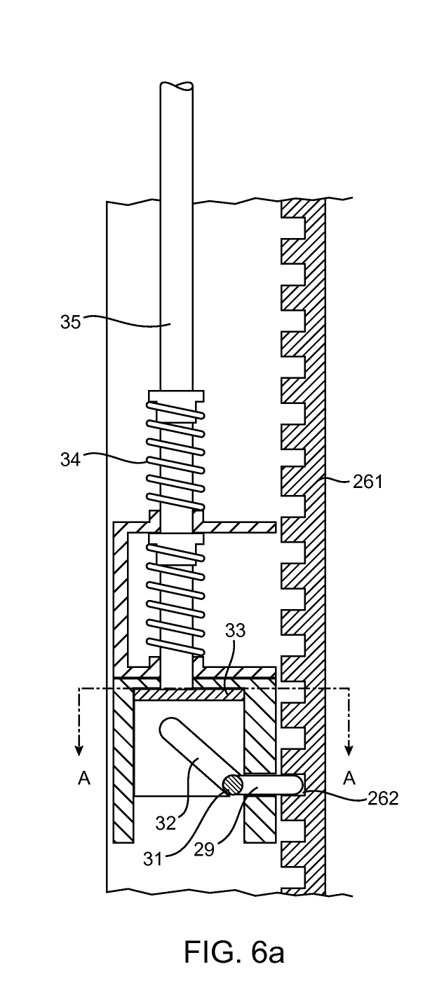

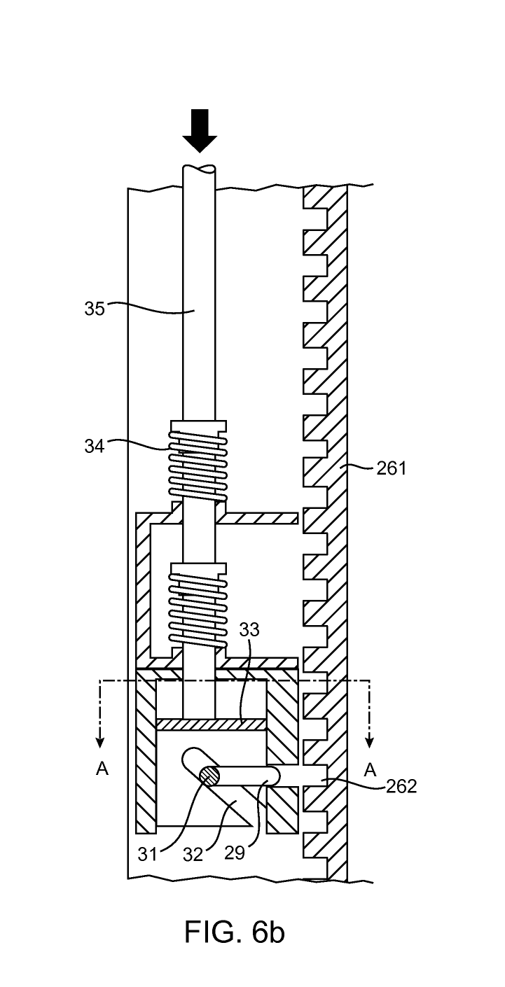

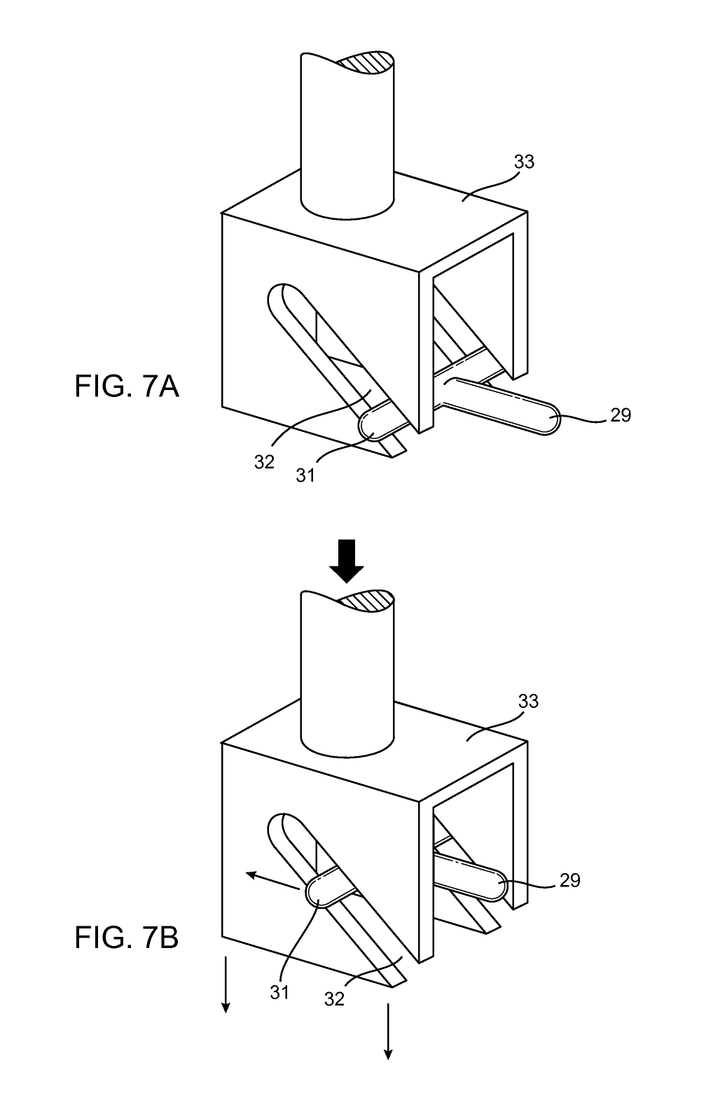

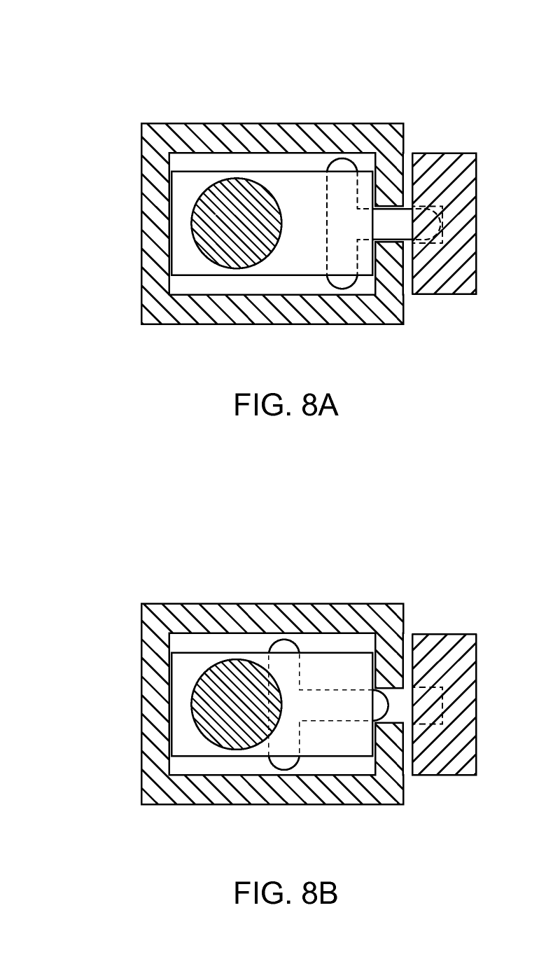

In a first embodiment of the invention, located on an inner wall on each side of the base panel within the channel of the frame of the base panel is a plurality of slots to form a vertical rack 261. FIG. 5c illustrates a vertical rack 261 on the right side of the base panel. A similar vertical rack is also present on the left side of the base panel. A pair of user operable press buttons 50 are located along the top edge of the display unit, one on each end of the top edge. As illustrated in FIGS. 5c and 5d, each of the press buttons is operably connected to a push rod 35. The push rod 35 is adjacent to the outer edge of the interior panel 24. Referring to FIG. 6a, a compression spring 34 is located along the push rod. At the bottom of the push rod is a mobile housing assembly 33 consisting of a recess or cavity 32. Situated within the cavity is a cross pin 31. The cross pin is perpendicularly connected to a locking pin 29 in a T formation. The cross pin resides within the recess 32 of the mobile housing assembly 33. It is to be understood that the structural components described herein are present on both sides of the display unit.

FIG. 6a shows the use of the interlocking mechanism wherein the user operable press buttons 50 are depressed simultaneously to cause the spring loaded push rod 35 to push down on the mobile housing assembly thereby lowering the vertical position of the mobile housing assembly. This in turn results in the cross pin 31 to move along a path of least resistance and move to a changed position within the recess or cavity 32 such that the locking pin 29 retracts away from and disengage from the vertical rack. Once the locking pin 29 is retracted away and disengaged from the vertical rack 261 of the interlocking mechanism, the elevation of the display screen can be appropriately adjusted up or down.

Referring to FIG. 6b, when the user operable press buttons 50 are released, the spring loaded push rod 35 moves to a more vertically elevated position causing the height of the mobile housing assembly 33 to be raised such that the cross pin 31 moves to the original position within the recess or cavity 32, This results in the locking pin 29 to move towards and to re-engage within a slot of the vertical rack 261. The complementary interlocking mechanism as that illustrated in FIGS. 6a and 6b is also present on the opposing side of the interior panel 24. Elevation of the height of the display panel and the interior panel will be accomplished by simultaneous operation of both the right and left interlocking mechanisms as described herein.

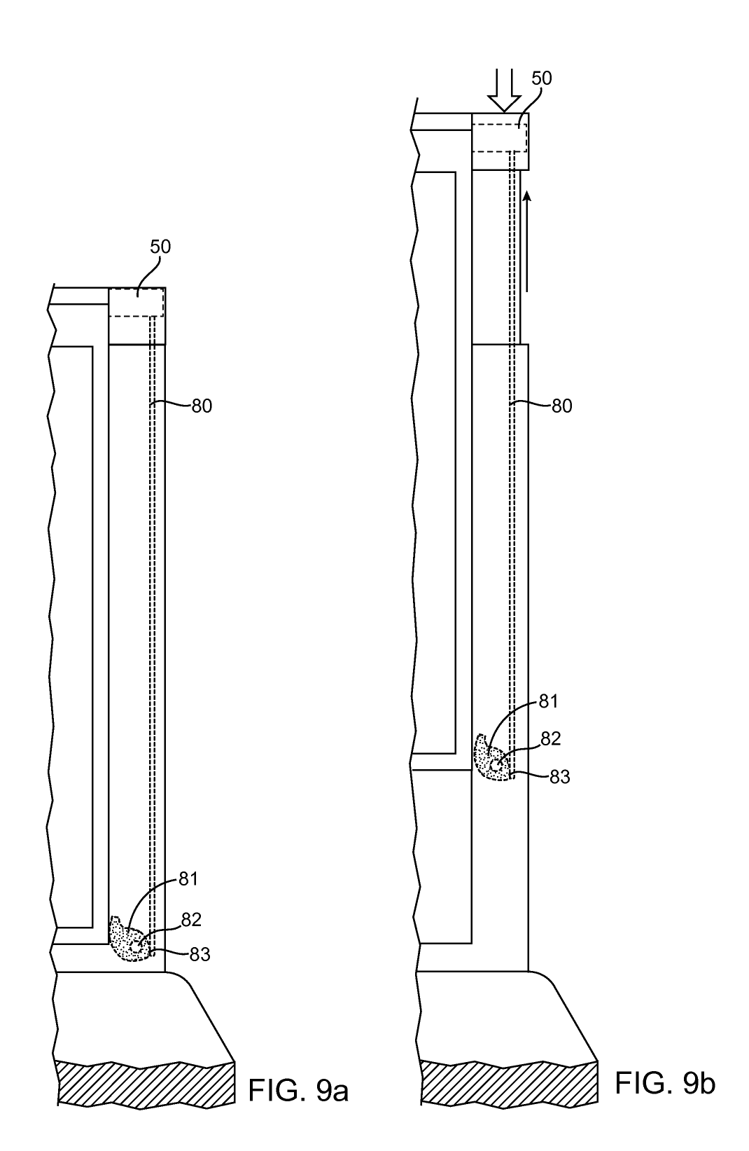

A second embodiment of the invention comprises a spring loaded pivotable locking mechanism. Details of this embodiment will be explained in reference to FIGS. 9a and 9b. The user operable press buttons 50 as described in FIG. 1 are each connected to a push rod 80 as shown in FIGS. 9a and 9b. On each side of the base panel 26, contained within the channel 84 forming the frame for the base panel, is a spring loaded pivotable locking mechanism 81. At the center of the locking mechanism is a connecting means 82 for attaching the pivotable locking mechanism to an interior wall of channel 84. In a resting position, an outer most edge of the locking mechanism 81 rests firmly against interior panel 24 such that the interior panel 24 and display panel 22 are secured in place and cannot travel vertically upward or downward. In order to elevate the display panel 22 and the interior panel 24, the user would depress the press buttons 50 on both sides simultaneously so as to trigger the push rod 80 to travel down on each side and press down on a protrusion 83 on the pivotable locking mechanism 81 whereby, the pivotable locking mechanism will rotate clock-wise and away from the interior panel 24 so as to remove all contact between the interior panel and the pivotable locking mechanism and thereby allowing the user to raise or lower the interior panel 24 and the display panel 22 to a desired height. Upon releasing the press button 50, the push rod 80 retracts upwards and away from protrusion 83 and thereby causes the pivotable locking mechanism 81 to rotate counter clock-wise so as to make a pressurized contact against the interior panel 24 and come into a resting position as described above. In one aspect, the pivotable locking mechanism comprises a rubber type material with sufficient resistance to create a pressurized contact with the interior panel 24 when in the resting position. The complementary interlocking mechanism as that illustrated in FIGS. 9a and 9b is also present on the opposing side of the interior panel 24 in this embodiment of the invention.

One of skill will recognize that any number of variations may be made to the details of the embodiments of the invention described herein without departing from the underlying principles or concepts thereof.

1. A portable computer comprising:
a main unit;
a display unit comprising:
a display screen panel and an interior panel;
an interlocking means comprising a movable housing assembly along two vertical sides of the interior panel; and
a base panel, comprising means of interlocking the base panel with the movable housing assembly.

2. The portable computer of claim 1, wherein the display screen panel of the display unit is rotationally coupled with the interior panel of the display unit along a top edge.

3. The portable computer of claim 1, wherein the main unit is rotationally coupled with the display unit along one side.

4. The portable computer of claim 2, wherein the base unit further comprises a groove along a surface.

5. The portable computer of claim 4, wherein said groove provides a means for holding reference material.

6. The portable computer of claim 1 wherein said display screen panel is rotationally coupled to said interior panel along an edge of said display screen panel whereby the display screen panel may be pivoted to change a viewing angle of said display screen panel.

7. The portable computer of claim 1, wherein the base panel further comprises a channel along each of two vertical sides to receive the interior panel and the display panel.

8. The portable computer of claim 7, wherein said channel comprises a plurality of slots to collectively form a vertical rack along an inner surface of said channel.

9. The portable computer of claim 8, wherein each of the plurality of slots is designed to receive a locking pin protruding from the movable housing assembly.

10. An interlocking mechanism comprising:
a plurality of slots arranged in a vertical pattern along an inner edge of a channel;
a movable housing assembly comprising a spring loaded push rod;
a T shaped pin comprising two longitudinal bars attached to each other in a perpendicular layout wherein the first of said two longitudinal bars is situated within a cavity of said movable housing assembly and the second of said two longitudinal bars is extendable into one of said plurality of slots.

11. An interlocking mechanism comprising a push rod operably connected to a spring loaded pivotable means wherein lowering or raising of the push rod results in a clock wise or counter clockwise orientation of the spring loaded pivotable means.

12. A method of elevating a display screen of a portable computer comprising:
providing a portable computer comprising a main unit and a display unit comprising a display screen panel coupled to an interior panel, an interlocking means including a movable housing assembly along two vertical sides of the interior panel and a base panel comprising for securing the base panel with the movable housing assembly;
depressing at least two buttons on the display unit to disengage the interlocking means from the base panel;
elevating the display panel and the interior panel to a height above the main unit; and releasing the at least two buttons to secure the display panel and the interior panel at a desired height by re-engaging the interlocking means.

13. The method of claim 12, wherein the desired height is at a location where the base of the display panel is at least about 8 inches above the main unit.

14. The method of claim 12, wherein the desired height is at a location where the base of the display panel is at least about 50% higher than an original un-elevated position of the display unit.
